(19) United States
(12) Patent Application Publication
(10) Pub. No.: US 2015/0263139 A1
(43) Pub. Date: Sep. 17, 2015

(54) SEMICONDUCTOR DEVICE

(71) Applicant: KABUSHIKI KAISHA TOSHIBA, Tokyo (JP)

(72) Inventor: Kenichi FUJII, Yokkaichi Mie (JP)

(21) Appl. No.: 14/617,385

(22) Filed: Feb. 9, 2015

Related U.S. Application Data
(60) Provisional application No. 61/951,832, filed on Mar. 12, 2014.

(51) Int. Cl. H01L 29/66; H01L 29/51; H01L 29/06; H01L 21/02; H01L 21/31; H01L 49/02; H01L 21/306; H01L 29/788; H01L 29/423; H01L 21/28; H01L 27/115; H01L 27/07; H01L 21/311

(52) U.S. Cl. CPC H01L 29/66825; H01L 27/0738; H01L 29/518; H01L 27/0733; H01L 29/0688; H01L 21/02532; H01L 21/31; H01L 21/31111; H01L 21/306; H01L 29/66545; H01L 21/02595; H01L 29/788; H01L 29/42324; H01L 21/28273; H01L 27/11521; H01L 27/11526; H01L 28/20; H01L 28/40

(57) ABSTRACT

A semiconductor device includes a memory cell transistor in which a first insulation film, a first conductive layer, a second insulation film, and a second conductive layer are sequentially stacked on a semiconductor substrate, and a peripheral circuit element in which a third insulation film, a third conductive layer, a fourth insulation film, a fourth conductive layer are sequentially stacked on the semiconductor substrate and which has a contact electrically connected to the third conductive layer. In the semiconductor substrate, a recess is formed at least in a region immediately below the contact. The third conductive layer is also formed within the recess, and a film thickness of the third conductive layer in the recess is thicker than a film thickness of the first conductive layer.

### CROSS-REFERENCE TO RELATED APPLICATION

This application is based upon and claims the benefit of priority from U.S. Provisional Patent Application No. 61/951,832, filed Mar. 12, 2014, the entire contents of which are incorporated herein by reference.

### FIELD

Embodiments described in the specification relate to a semiconductor device.

### BACKGROUND

In a semiconductor device including a memory cell having a floating gate electrode, it is possible to form peripheral circuit elements including a resistance element, a capacitance element, or the like using the same conductive layer which was used to form the floating gate electrode in the memory cells. In the resistance element in which the conductive layer is a resistor, contacts are formed on either side of the portion of the conductive layer that is the resistor. Since the capacitance element also applies a potential to the conductive layer, the contacts are formed on opposed surfaces of the conductive layer. The contacts that are formed for the conductive layer may be created by forming a hole simultaneously with that of other contacts coming into contact with the semiconductor substrate, and then filling the hole with a conductor. However, during the process of forming the hole for the resistor or capacitor contact simultaneously with the contacts coming into contact with the semiconductor substrate, the hole may be formed too deep, such that it likewise comes into contact with the semiconductor device, shorting the resistor or capacitor to the substrate.

### BRIEF DESCRIPTION OF THE DRAWINGS

FIG. 1 is one example of an equivalent circuit illustrating a schematic electrical configuration of a first embodiment of a memory device.

FIG. 2A is one example of a plan view illustrating a layout of a memory cell region, FIG. 2B is one example of a plan view illustrating a layout of a low withstand voltage transistor of a peripheral circuit, FIG. 2C is one example of a plan view illustrating a layout of a high withstand voltage transistor of the peripheral circuit, and FIG. 2D is one example of a plan view illustrating a layout of a resistance element of the peripheral circuit.

FIG. 3A is a portion taken along line 3A-3A in FIG. 2A, FIG. 3B is one example of a vertical cross-sectional side view of a portion taken along line 3B-3B in FIG. 2A, FIG. 3C is a portion taken along line 3C-3C in FIG. 2B, FIG. 3D is one example of a vertical cross-sectional side view of a portion taken along line 3D-3D in FIG. 2C, FIG. 3E is a portion taken along line 3E-3E in FIG. 2D, and FIG. 3F is one example of a vertical cross-sectional side view of a portion taken along line 3F-3F in FIG. 2D.

FIGS. 4A to 4F to FIGS. 16A to 16F illustrate one example of a vertical cross-sectional side view of one step of manufacturing and each sectional view corresponds to respective cutting positions of FIGS. 3A to 3F.

FIG. 17 is one example of a plan view illustrating a layout of a capacitor of a peripheral circuit illustrating a second embodiment.

FIG. 18 is one example of a vertical cross-sectional side view of a portion of the capacitor illustrated along line 18-18 in FIG. 17.

### DETAILED DESCRIPTION

According to an embodiment, a semiconductor device includes a memory cell transistor in which a first insulation film, a first conductive layer, a second insulation film, and a second conductive layer are sequentially stacked on a semiconductor substrate, and a peripheral circuit element in which a third insulation film, a third conductive layer, a fourth insulation film, a fourth conductive layer are sequentially stacked on the semiconductor substrate and which has a contact electrically connected to the third conductive layer. In the semiconductor substrate, a recess is formed at least in a region immediately below the contact. The third conductive layer is also formed within the recess, and a film thickness of the third conductive layer in the recess is thicker than a film thickness of the first conductive layer.

### First Embodiment

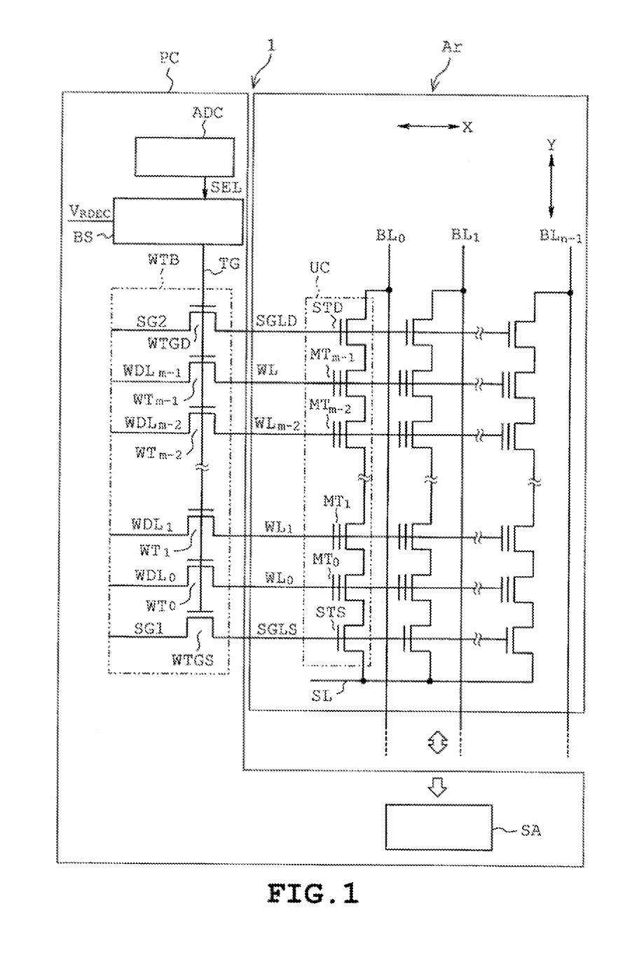

Hereinafter, a first embodiment applied to an NAND type flash memory device will be described with reference to FIGS. 1 to 16. Moreover, the drawings are schematic and a relationship between thicknesses and planar dimensions, the ratio of the thicknesses of each layer, and the like do not necessarily accord with those of an actual device. Furthermore, vertical and horizontal directions also illustrate relative directions assuming that a side of a circuit formation surface is a top in the semiconductor substrate described below, and do not necessarily accord with those based on the gravitational acceleration direction.

FIG. 1 schematically illustrates a block view of an electrical configuration of a NAND type flash memory device. As illustrated in FIG. 1, a NAND type flash memory device 1 includes a memory cell array Ar in which a plurality of memory cells are disposed in a matrix pattern or shape, and a peripheral circuit PC which performs reading/writing/erasing of each memory cell of the memory cell array Ar, and includes an input and output interface circuit (not illustrated) and the like.

A plurality of cell units UC are disposed in the memory cell array Ar. The cell unit UC is configured such that an individual selector gate transistor STD is connected to a side of each of respective bit lines BL₀ . . . BLₙ₋₁, an individual selector gate transistor STS is connected to a side of each source line SL, and, for example, 32 memory cell transistors MT₀ . . . MTₘ₋₁ are connected in series between each two selector gate transistors STD-STS.

In one block, the cell units UC of n columns are disposed in an X direction (row direction; the horizontal direction in FIG. 1) that is a first direction. In the memory cell array Ar, a plurality of blocks is disposed in a Y direction (column direction; the vertical direction in FIG. 1) that is a second direction. Furthermore, in order to simplify the description, only one block is illustrated in FIG. 1.

A peripheral circuit region is provided on the periphery of a memory cell region and the peripheral circuit PC is disposed on the periphery of the memory cell array Ar. The peripheral circuit PC includes a booster circuit BS having an address decoder ADC, a sense amplifier SA, and a charge pump circuit; a transfer transistor section WTB; and the like. The address decoder ADC is electrically connected to the transfer transistor section WTB through the booster circuit BS. The peripheral circuit PC includes a resistance element R as the peripheral circuit element.

The address decoder ADC selects one block B of the memory array AR in response to an address signal applied from the outside thereof. The booster circuit BS is configured such that a drive voltage V_{RDEC} is supplied from the outside of the address decoder ADC and the drive voltage V_{RDEC} to which a select signal SEL of the block B is applied is boosted, and then a predetermined voltage is supplied to respective transfer gate transistors WTGD, WTGS, WT₀ to WTₘ₋₁ through a transfer gate line TG.

The transfer transistor section WTB includes a transfer gate transistor WTGD that is provided corresponding to the select gate transistor STD, a transfer gate transistor WTGS that is provided corresponding to the select gate transistor STS, and word line transfer gate transistors WT₀ to WTₘ₋₁ that are respectively provided corresponding to respective memory cell transistors WT₀ to WTₘ₋₁. A transfer transistor section WTB is provided in each block B.

One of the drain or source of the transfer gate transistor WTGD is connected to a selector gate driver line SG2 and the other is connected to a selector gate line SGLD. One of the drain or source of the transfer gate transistor WTGS is connected to a selector gate driver line SG1 and the other is connected to a selector gate line SGLS. Furthermore, one of the drain or source of respective transfer gate transistors WT₀ to WTₘ₋₁ is connected to respective word line drive signal lines WDL₀ to WDLₘ₋₁ and the other of the source and drain is connected to respective word lines WL₀ to WLₘ₋₁ provided inside the memory cell array Ar (memory cell region M).

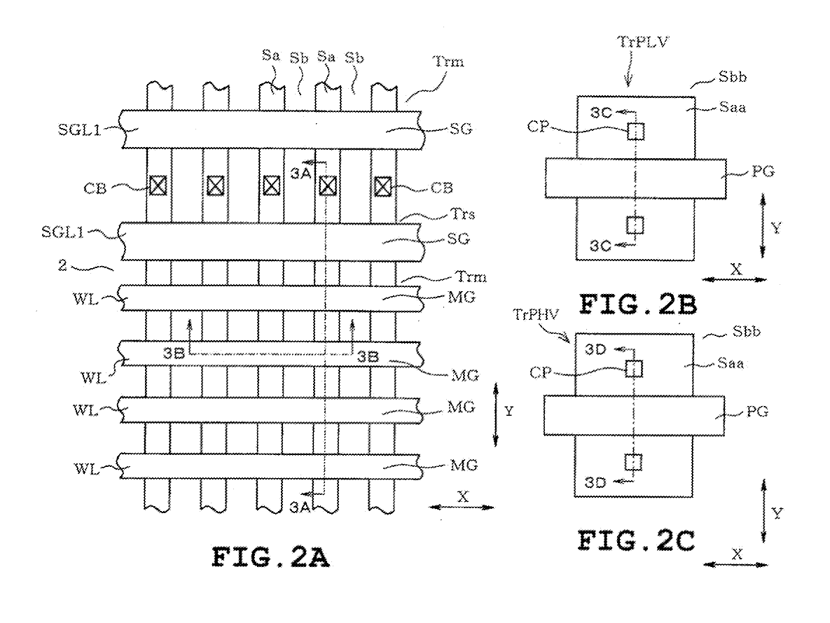

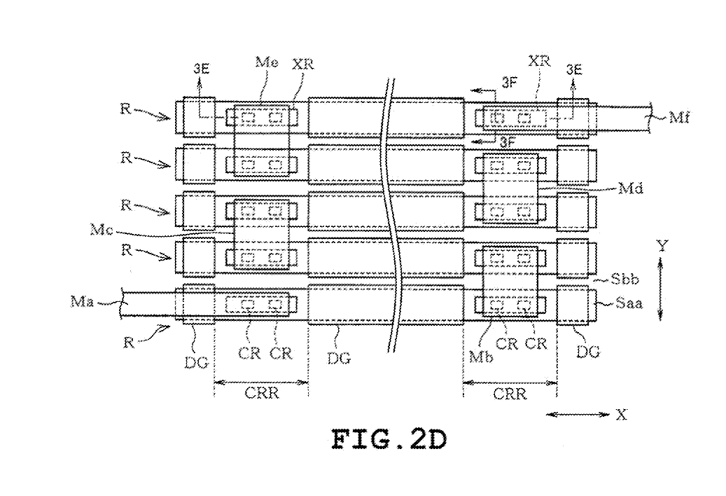

A gate electrode SG of the selector gate transistor STD of the plurality of cell units UC disposed in the X direction is electrically connected by the selector gate line SGLD. Similarly, the selector gate transistor STS of the plurality of cell units UC disposed in the X direction is electrically connected by the selector gate line SGLS. The source of the selector gate transistor STS is commonly connected to the source line SL. Moreover, the selector gate transistors STD and STS are referred to as a selector gate transistor Trs in the description after FIG. 2.

Respective gate electrodes MG of the memory cell transistors MT₀ to MTₘ₋₁ of the plurality of cell units UC disposed in the X direction are electrically connected by the word lines WL₀ to WLₘ₋₁. The memory cell transistors MT₀ to MTₘ₋₁ are referred to as a memory cell transistor Trm in the description after FIG. 2.

Respective transfer gate transistors WTGD, WTGS, WT₀ to WTₘ₋₁ are commonly connected to each other by the transfer gate line TG and are connected to a booster voltage supply terminal of the booster circuit BS. The sense amplifier SA is connected to the bit lines BL₀ to BLₙ₋₁ and is connected to a latch circuit that temporarily stores data when reading the data. Moreover, the low withstand voltage transistor formed in the peripheral circuit region is referred to as TrPLV and the high withstand voltage transistor is referred to as TrPHV, and those names are indicated after FIG. 2.

FIG. 2A illustrates a plan view of a layout pattern of a portion of the memory cell region. As illustrated in FIG. 2A, element isolation regions Sb having a STI (shallow trench isolation) structure that fills a trench extending into the insulation film are formed in the memory cell region of a P type silicon semiconductor substrate 2 and extend along the Y direction of FIG. 2A. The plurality of element isolation regions Sb are formed at predetermined intervals in the X direction as shown in FIG. 2A. Therefore, element formation regions Sa are formed between the element isolation regions Sb and likewise extend along the Y direction, and are spaced in the X direction, of FIG. 2A.

Word lines WL extend in the X direction (X direction in FIG. 2A) orthogonal to the element formation regions Sa. A plurality of word lines WL are formed at predetermined intervals in the Y direction in FIG. 2A. The gate electrodes MG of the memory cell transistors Trm are provided above the element formation regions Sa where the word lines WL cross the element formation regions Sa.

A plurality of memory cell transistors Trm adjacent one another in the Y direction become a portion of an NAND column (memory cell string). Respective selector gate transistors Trs are provided at the opposed ends of the memory cell string. A plurality of selector gate transistors Trs are provided, and located on the element formation regions Sa, where the selector gate line SGL1 crosses the element formation regions. A bit line contact CB is formed on the element formation region Sa between adjacent gate electrodes SG-SG in the Y direction.

FIGS. 2B and 2C respectively illustrate a layout of the low withstand voltage transistor TrPLV and the high withstand voltage transistor TrPHV of peripheral circuit region. In FIGS. 2B and 2C, an element isolation region Sbb is formed in the silicon substrate 2 so as to leave, in the semiconductor substrate, a rectangular element formation region Saa. Moreover, the X direction and the Y direction indicated in FIGS. 2A and 2B illustrate a relationship with a cross-sectional view, and the low withstand voltage transistor TrPLV and the high withstand voltage transistor TrPHV are not limited to the illustrated arrangement directions, and may be disposed in different directions.

The low withstand voltage transistor TrPLV and the high withstand voltage transistor TrPHV are individually provided on different rectangular element formation regions Saa. A gate electrode PG is formed to cross over the element formation regions Saa, and source and drain regions are formed by dopant diffusion are provided on either side of the gate electrode PG. Contact plugs CP, which electrically connect to the silicon substrate 2, are formed in the source and the drain regions.

FIG. 2D is a plan view of the resistance element R formed as the peripheral circuit element in the peripheral circuit region and, for example, as illustrated in FIG. 2D, five resistance elements R are disposed in parallel. Moreover, the X direction and the Y direction indicated in FIG. 2D illustrates a relationship with a cross-sectional view and is not limited to the illustrated arrangement directions, and the resistance elements R may be disposed in different directions.

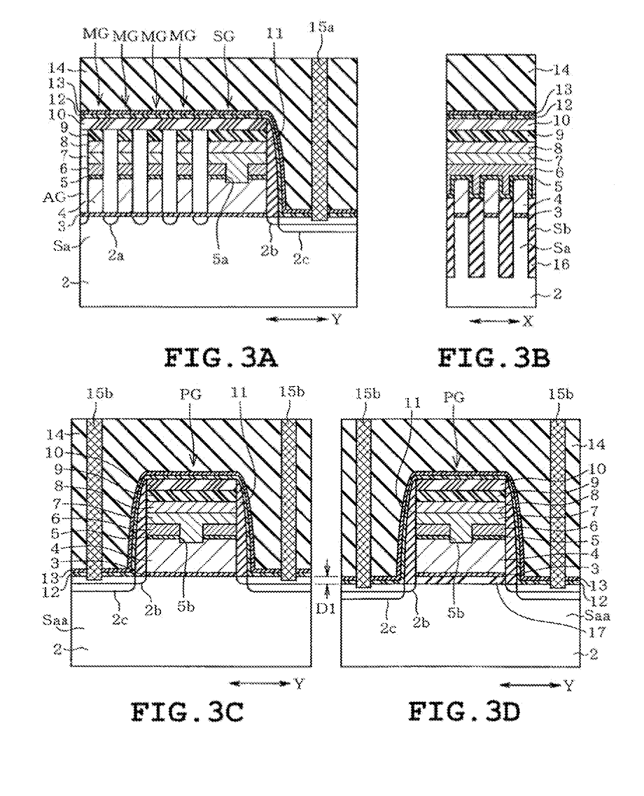

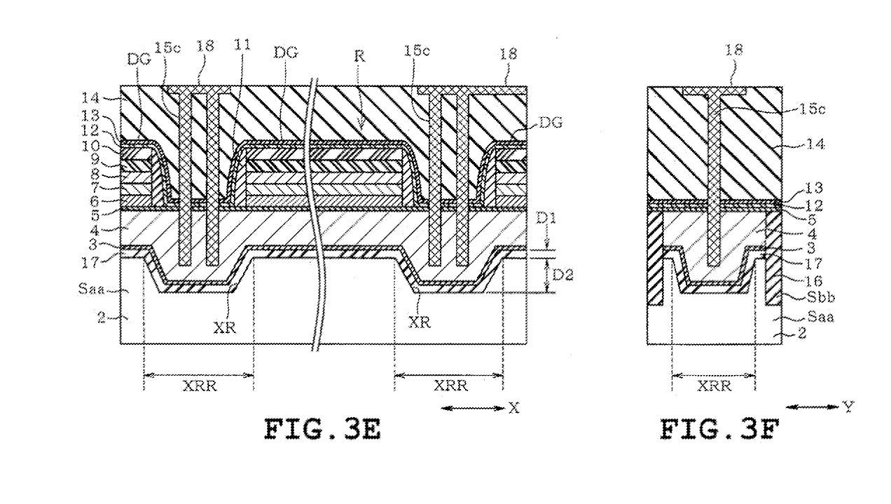

The resistance element R is formed on a rectangular element formation region Saa that is isolated by the element isolation regions Sbb. For example, the element formation region Saa is provided in a rectangular shape extending in the X direction of FIG. 2D. The conductive layer of a resistor of the resistance element R is formed on the upper section thereof with an insulation film disposed therebetween. The resistance element contacts CR are formed in pairs in opposed end sections of the conductive layer formed on the element formation region SaaAs shown in FIG. 2D, two contacts CR are spaced in the X direction, the direction in which the resistor extends. Furthermore, directly below the pairs of contacts CR, a rectangular recessed portion XR (FIG. 3E) is formed inwardly of the silicon substrate 2 such that the contacts CR extend thereunto. Here, it is preferable that the recess XR be included within the element formation region Saa. To either side of the pair of resistor contacts CR, a dummy gate DG is formed on the upper surface of the conductive layer of a portion excluding a formation region CRR of the contact CR when forming the gate structure of the memory cell transistor. The conductive layer between spaced pairs of contacts CR functions as the resistance element R. Furthermore, the contacts CR of five resistance elements R are connected to each other between adjacent resistance elements by wiring patterns Ma to Mf disposed in the upper surface section of an interlayer insulation film. As a result, five resistance elements R may be connected in series. Moreover, the number of, or connection method, of the resistance elements R is not limited to the illustration and the resistance elements R may be connected so as to have a resistance value set by a suitable number or resistance elements in series.

FIGS. 3A to 3F schematically illustrate a cross section structure of the element configuration inside the memory cell region and the peripheral circuit region, respectively. FIG. 3A is a vertical cross-sectional view of the formation region of the memory cell transistor Trm, the select gate transistor Trs, and the bit line contact CB between the select gate transistors Trs-Trs in the Y direction. FIG. 3B is a vertical cross-sectional view of the memory cell transistor Trm in the X direction that is the formation direction of the word line WL. FIG. 3C is a vertical cross-sectional view of the transistor TrPLV of the peripheral circuit. FIG. 3D is a vertical cross-sectional view of the transistor TrPHV of the peripheral circuit. FIGS. 3E and 3F are vertical cross-sectional views of the resistance element R.

Next, a configuration of the memory cell transistor Trm and the select gate transistor Trs of the memory cell region will be described with reference to FIGS. 3A and 3B. A tunnel insulation film 3 as the first insulation film is formed on the upper surface of the silicon substrate 2, and the gate electrode MG of the memory cell transistors Trm and the gate electrode SG of the selector gate transistors Trs are formed on the upper surface thereof. The memory cell transistor Trm is configured to include the tunnel insulation film 3, the gate electrode MG, and a source/drain region 2a that is formed in the silicon substrate 2 on either side thereof. The plurality of memory cell transistors Trm is formed adjacent to each other in the Y direction. A selector gate transistor Trs is formed adjacent to the ends of each string of memory cell transistors Trm.

The gate electrode MG of the memory cell transistor Trm includes a polycrystalline silicon film 4 that is the first conductive layer, an inter-electrode insulation film 5 that is the second insulation film, polycrystalline silicon films 6 and 7 that are the second conductive layer, a metal film 8 such as tungsten, and a silicon nitride film 9 sequentially formed on the first insulation film 3. For example, as the inter-electrode insulation film 5, an oxide-nitride-oxide (ONO) film, a nitride-oxide-nitride-oxide-nitride (NONON) film, an insulation film having a high dielectric constant, or the like is used.

The source/drain region 2a is provided in the surface layer of the silicon substrate 2 in locations between the gate electrodes MG-MG and between the gate electrodes SG-MG, and a lightly doped drain (LDD) region 2b corresponding to the drain region is provided in the surface layer of the silicon substrate 2 positioned between the gate electrodes SG-SG. The source/drain region 2a and the LDD region 2b may be formed in the surface layer of the silicon substrate 2 by diffusing dopants therein. Furthermore, a drain region 2c into which a high concentration of dopants are doped is formed in the surface layer of the silicon substrate 2 at the location between the gate electrodes SG-SG, thereby forming a LDD structure.

The gate electrode SG of the selector gate transistor Trs has a configuration substantially similar to that of the gate electrode MG of the memory cell transistor Trm. The polycrystalline silicon film 4, the inter-electrode insulation film 5, the polycrystalline silicon films 6 and 7, the metal film 8, the silicon nitride film 9 are sequentially formed on the gate insulation film 3. An opening 5a is provided in a center portion of the inter-electrode insulation film 5 and an electrically connecting state is achieved by contact between the polycrystalline silicon films 4 and 6 of the gate electrode SG.

An insulation film 10 is formed in the gate electrodes MG-SG so as to bridge across upper surfaces of the gate electrodes MG-SG on the upper surface of the silicon nitride film 9. For example, the insulation film 10 may use a silicon oxide film that is formed under a condition that avoid filling property thereof is low. The insulation film is thus not embedded in the openings between the memory gates MG and the memory gate MG and selector gate SG, and an air gap (a void portion) AG is provided between the memory gates MG and the memory gate MG and selector gate SG.

The air gap AG is not provided in the region between adjacent selector gate electrodes SG-SG and a spacer 11 is provided along the side surface of the gate electrode SG. The spacer 11 may be composed of, for example, a silicon oxide film and is formed so as to extend from the upper surface of the silicon substrate 2 to the upper surface portion of the gate electrode SG.

A silicon oxide film 12 and a silicon nitride film 13 are sequentially formed on the insulation film 10 so as to cover the surface of the silicon substrate 2 that is exposed on a bottom surface section of the surface of the spacer 11 on the insulation film 10 and between the selector gate electrodes SG-SG. An interlayer insulation film 14 is formed on the silicon nitride film 13 so as to fill the concave portion between the selector gate electrodes SG-SG and to cover the upper surface of the gate electrodes MG-SG. A contact plug 15a passes through the interlayer insulation film 14 from the upper section to the lower section and passes through the silicon nitride film 13 and the silicon oxide film 12 so as to reach the silicon substrate 2 in the region between the selector gate electrodes SG-SG.

In FIG. 3B illustrating a cross section of the memory cell transistor Trm in the X direction, showing the element formation regions Sa isolated by the element isolation region Sb in the X direction (X direction in FIG. 2A). The first insulation film 3 is provided on the element formation region Sa and the polycrystalline silicon film 4 that is the first conductive layer is provided thereon. For example, boron as the dopant is doped into the polycrystalline silicon film 4.

In the element isolation regions Sb, an element isolation insulation film 16 is filled and formed inside the concave portion of the silicon substrate 2, and an upper surface thereof reaches substantially the middle of a height of the polycrystalline silicon film 4. The second insulation film 5 is provided along surfaces of the polycrystalline silicon film 4 and the element isolation insulation film 16 so as to cover them. The polycrystalline silicon films 6 and 7 and the metal film 8 are provided, in order, on the element isolation insulation film 16. The silicon nitride film 9 is formed on the upper section of the metal film 8.

Next, configurations of the low withstand voltage transistor TrPLV and the high withstand voltage transistor TrPHV will be described with reference to FIGS. 3C and 3D.

In FIG. 3C, the low withstand voltage transistor TrPLV is provided with the gate insulation film 3 on the upper surface of the silicon substrate 2. The gate insulation film 3 may use the same material as that of the gate insulation film 3 of the memory cell transistor Trm and is formed having a film thickness that may function as a portion of the low withstand voltage transistor.

Furthermore, in FIG. 3D, the high withstand voltage transistor TrPHV is provided with a gate insulation film 17 and the gate insulation film 3 formed thereover as the third insulation film on the upper surface of the silicon substrate 2. Moreover, the gate insulation film 17 and the gate insulation film 3 may be integrally viewed when viewed from a cross section SEM and a cross section TEM. The gate insulation film 17 is formed having a film thickness that is thicker than that of the gate insulation film 3 and that may function as a portion of the high withstand voltage transistor. In this case, the withstand voltage as the high withstand voltage transistor TrPHV may be secured by the stack of the gate insulation films 3 and 17.

The height of the upper surface of the silicon substrate 2 is processed so as to be lower than that of the upper surface of the silicon substrate 2 in the region of the low withstand voltage transistor TrPLV by a height D1. The height D1 is substantially the same as the film thickness of the gate insulation film 17. That is, the upper surface of the substrate 2 is recessed in locations where the gate insulation film 17 is formed, such that the upper surface of the gate insulation film 17 is generally at the height of the upper surface of the silicon substrate 2 of the low withstand voltage transistor TrPLV. Moreover, the upper surface of the silicon substrate of the low withstand voltage transistor TrPLV is substantially the same as the upper surface of the silicon substrate 2 of the memory cell region.

The low withstand voltage transistor TrPLV and the high withstand voltage transistor TrPHV are provided with the gate electrode PG on the gate insulation film 3. The gate electrode PG has the polycrystalline silicon film 4 as a lower electrode film, the inter-electrode insulation film 5, the polycrystalline silicon films 6 and 7 as an upper electrode, and the metal film 8 formed in that order. The silicon nitride film 9 is formed on the metal film 8. The insulation film 10 that was used to cover the openings between the gates MG-MG and MG-SG and thus forming air gaps AG is formed on the silicon nitride film 9. In the gate electrode PG, an opening portion 5b is provided in a center portion of the second insulation film 5 and the polycrystalline silicon films 4 and 6 are electrically connected to each other by being in contact with each other through the opening portion 5b. Therefore, the lower layer electrode film and the upper layer electrode film are at the same potential during operation. A contact plug 15b is provided so as to form the source/drain region and an ohmic contact to the silicon substrate 2 by passing through the interlayer insulation film 14 from the upper section to the lower section thereof and further passing through the silicon nitride film 13 and the silicon oxide film 12.

Next, a cross-sectional structure of the resistance element R of the peripheral circuit region will be described with reference to FIGS. 3E and 3F. FIGS. 3E and 3F are one example of views illustrating respective cross-sectional structures of portions taken along line 3E-3E and line 3F-3F of FIG. 2D. The silicon substrate 2 is provided with the rectangular element formation region Saa surrounded by the element isolation region Sbb filled with the element isolation insulation film 16.

Furthermore, in region XRR of the element formation region Saa of the resistance element R, a recessed portion XR extending inwardly of the surface of the silicon substrate 2 (element formation region Saa) is formed. The recess of the recessed region XRR is provided to receive the end of a contact plug 15c therein, and thus underlies the contact plugs 15c when viewed from above. That is, the recessed portion XR is formed immediately below the contact plug CP. Here, the height of the surface of the silicon substrate 2 other than the recessed portion region XRR is processed so as to be the same as that of the upper surface of the silicon substrate 2 of the high withstand voltage transistor TrPHV. The gate insulation film 17 for the high withstand voltage transistor TrPHV is formed on the upper surface of the silicon substrate 2 and is adjusted so as to be the same height as that of the silicon substrate 2 of the memory cell transistor Trm and the low withstand voltage transistor TrPLV.

A bottom surface of the recessed portion XR is in a position that is lowered from the surfaces of the silicon substrate 2 in locations other than in the recessed region XRR to a depth D2 in a location to receive a bottom surface section of the contact plug 15c. The recessed region XRR is set in a region corresponding to the portion in which at least the contact plug 15c is disposed, but is not limited to that embodiment and may be provided to be suitably extended, and may be set in a narrower region. Furthermore, the recessed region XRR may be an entire region of the element formation region Saa as long as it is possible to adjust a resistance value of the resistance element R.

The gate insulation films 17 and 3 as the third insulation film are formed on the upper surface of the silicon substrate 2. The gate insulation films 3 and 17 may be composed of silicon oxide. Furthermore, the gate insulation films 17 and 3 are conformably formed on the surface of the recessed portion XR. The polycrystalline silicon film 4 configuring the third conductive layer that is the resistor is provided on the upper surface of the gate insulation film 3 so as to fill the concave portion XR. For example, phosphorus or arsenic is doped in the polycrystalline silicon film 4 and then the polycrystalline silicon film 4 is n-type polycrystalline silicon. Furthermore, the upper surface of the polycrystalline silicon film 4 may be flat. The inter-electrode insulation film 5 as the fourth insulation film is provided on the upper section of the polycrystalline silicon film 4. The polycrystalline silicon films 6 and 7, and the metal film 8 as the fourth conductive layer are provided in this order on the upper section of the inter-electrode insulation film 5 (corresponding to the film configuration configuring a control gate electrode in the memory cell transistor Trm). The silicon nitride film 9 and the insulation film 10 are provided on the upper section of the metal film 8. The portions of the inter-electrode insulation film 5, the polycrystalline silicon films 6 and 7, and the metal film 8 form a dummy gate DG.

The spacer 11 is formed on a side wall of the dummy gate s DG using a silicon oxide film. The silicon oxide film 12 and the silicon nitride film 13 are formed so as to cover an upper surface of the dummy gate section DG and the surface of the inter-electrode insulation film 5 that is exposed between the side surface of the spacer 11 and the dummy gate section DG.

The interlayer insulation film 14 is, for example, a silicon oxide film and it fills the recessed portion between the dummy gates DG, and it is formed on the upper surface of the silicon nitride film 13 so as to cover the dummy gates DG. Two contact plugs 15c extend through the interlayer insulation film 14, the silicon nitride film 13, the silicon oxide film 12 and the inter-electrode insulation film 5, and terminate within the polycrystalline silicon film 4 to form the contacts CR extending between adjacent dummy gates DG.

A lower end of the contact plug 15c is positioned within the polycrystalline silicon film 4 and spaced from the bottom surface of the recessed portion XR. In FIG. 3E, the lower end of the contact plug 15c is in a position lower than the surface of the silicon substrate 2 in locations other than the recessed region XRR and higher than the bottom surface of the silicon substrate 2 of the recessed region XRR. Moreover, the lower end of the contact plug 15c may be higher than the surface of the silicon substrate 2 in locations other than the concave portion region XRR, so long as the lower end thereof is positioned in the inside of the polycrystalline silicon film 4. In this case, in the lower section of the contact plug 15c, since the polycrystalline silicon film 4 is extended into the semiconductor substrate 2 by the depth D2 from the surface of the silicon substrate 2 other than in the concave portion region XRR, the lower end of the contact plug 15c is unlikely to reach the surface of the silicon substrate 2 even if the openings therefore are overetched.

Each of two contact plugs 15c on either side of adjacent dummy gates DG come into contact with the polycrystalline silicon film 4 making ohmic contact. The polycrystalline silicon film 4 is insulated from the upper and lower layers, and is also insulated from the element isolation insulation film 16 in the Y direction by providing the gate insulation film 3 on the lower surface and the inter-electrode insulation film 5 on the upper surface thereof. Therefore, the polycrystalline silicon film 4 extending between the contact plugs 15c on opposite sides of each dummy gate functions as the resistor element R that is connected between each of two contact plugs 15c located to either side of the dummy gate.

In the configuration described above, where the resistance element R is provided as the peripheral circuit element of the NAND type flash memory device 1, the recessed portion XR is provided in the silicon substrate 2 of the formation region of the contact plug 15c and the film thickness of the polycrystalline silicon film 4 in that portion is more thickly formed. Therefore, even if the position of the lower end of the contact plug 15c is lower than the surface (the upper surface of the silicon substrate 2 of the high withstand voltage transistor TrPHV, or the upper surface of the silicon substrate 2 of the memory cell region) of the silicon substrate 2 other than in the recessed region XRR, the deeper extent of the polycrystalline silicon film 4 allows a larger process window, i.e., etch time of the contact holes, to ensure the contacts in the transistor regions reach the silicon substrate 2 but the contacts for the resistors do not reach the silicon substrate 2. Additionally the thickness of the polycrystalline silicon film extending between two recessed portions effects the resistance value between the two recessed portions, and thus of the resistor, and this thickness may be independently set and formed without risk of the contacts for the resistor being overetched into the underlying silicon substrate.

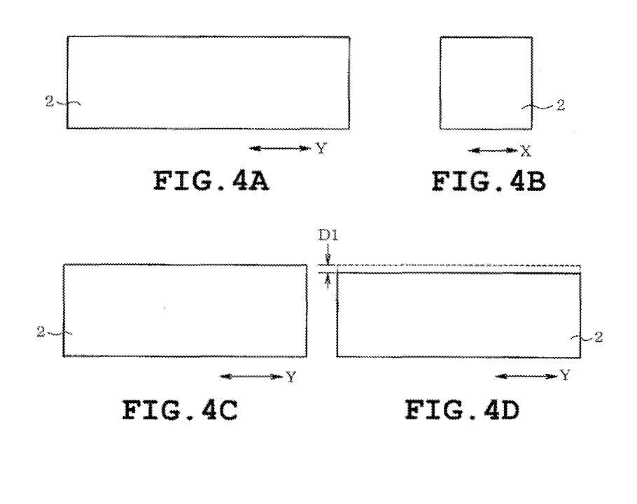

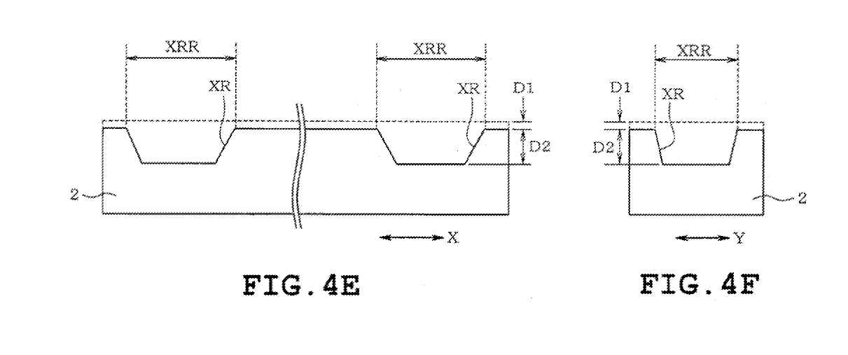

Next, one example of a manufacturing method of the configuration described above will be described with reference to FIGS. 4 to 16. Moreover, the embodiment is described mainly on the characteristic portions, but other processes may be added between respective processes and the process may be deleted if it is a general process. Furthermore, respective processes may be appropriately interchanged if it is practically possible.

First, in FIGS. 4A to 4F, the upper surface (FIGS. 4D, 4E, and 4F) of the silicon substrate 2 in the area of the high withstand voltage transistors TrPHV and the resistance elements R is processed so as to be recessed by depth D1. A region other than the portion to be recessed is covered with a resist, which includes patterned openings in regions where the semiconductor substrate 2 is to be recessed, and the substrate is processed so as to recess the surface by etching thereof. The etching may be performed, for example, using a reactive ion etching (RIE) method. Furthermore, the etching depth D1 is set so that the upper surface of the gate insulation film 17 for the high withstand voltage will be the same height as the upper surface of the silicon substrate 2 of the memory cell region.

Furthermore, the recess of the recessed portion XR, having the depth dimension D2, is further formed on the upper surface of the silicon substrate 2 in the recessed region XRR where the resistance element R is formed. Simultaneously, the other regions of the substrate are covered by resist, which is patterned by photolithography to have openings therein corresponding to locations where the recessed portions XR are to be formed, and the recesses of the recessed portions XR are formed by etching using the RIE method. In this case, the side wall surface of the concave portion XR may be formed in a state of having a taper (inclined surface). Thereafter the resist is stripped from the substrate. The depth dimension D2 may be adjusted in a range, for example, from 20 nm to 100 nm.

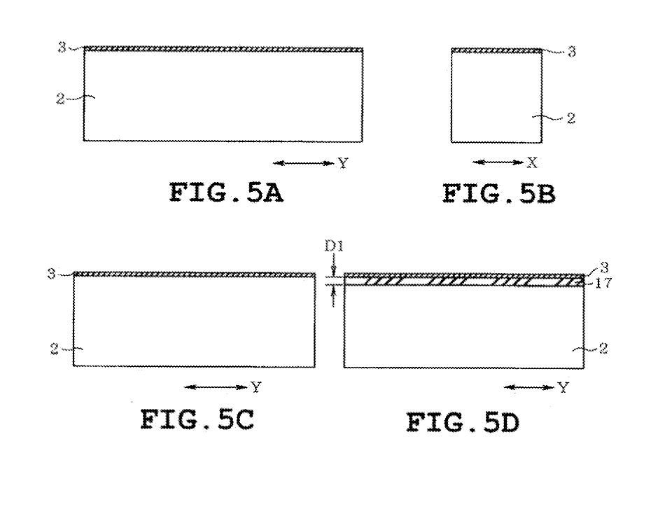

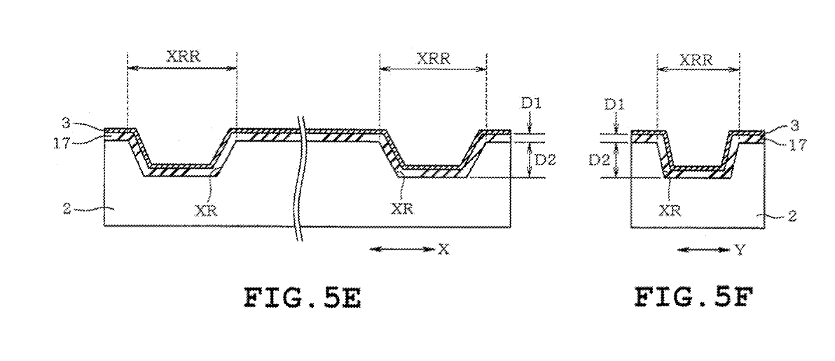

Next, as illustrated in FIGS. 5A to 5F, the gate insulation film 17 and the gate insulation film 3 are sequentially formed on the upper surface of the silicon substrate 2. In this case, the gate insulation film 17 for the high withstand voltage that is initially formed is selectively formed on the surface of the silicon substrate 2 in regions where the high withstand voltage transistors TrPHV and the resistance elements R are to be formed. The selective formation of the gate insulation film 17 may be performed by blanket depositing the gate insulation film 17 over the entire substrate, followed by removal of those portions of the gate insulation film 17 other than the areas where the high withstand voltage transistor TrPHV and the resistance element R are formed. Furthermore, the selective formation may be performed using a method other than the above method. The film thickness of the gate insulation film 17 is set to have sufficient thickness to function as a gate insulation film of a high withstand voltage transistor TrPHV.

Thereafter, the gate insulation film 3 is formed on the entire surface of the substrate 2. The gate insulation film 3 functions as the gate insulation film of the memory cell transistor Trm, the selector gate transistor Trs, or the low withstand voltage transistor TrPLV. In this case, the gate insulation film 3 is also formed on the upper surface of the gate insulation film 17 of the high withstand voltage transistor TrPHV or the resistance element R, but may not be provided there. Moreover, the gate insulation film 3 is also deposited over the gate insulating film 17 in the recessed portions XR.

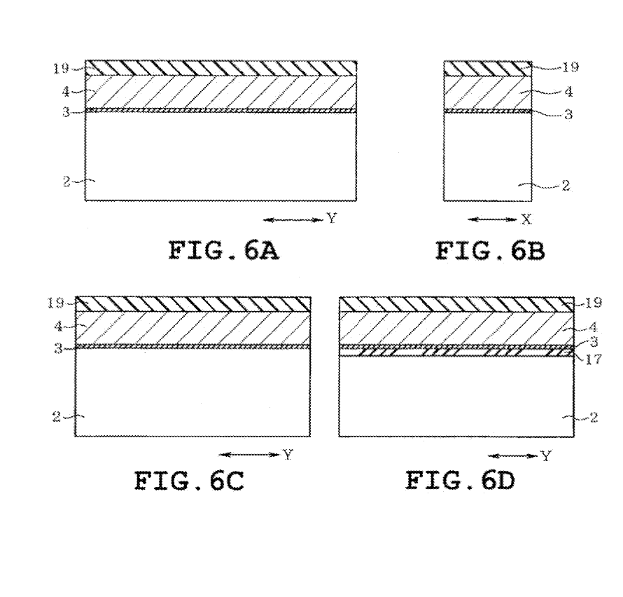

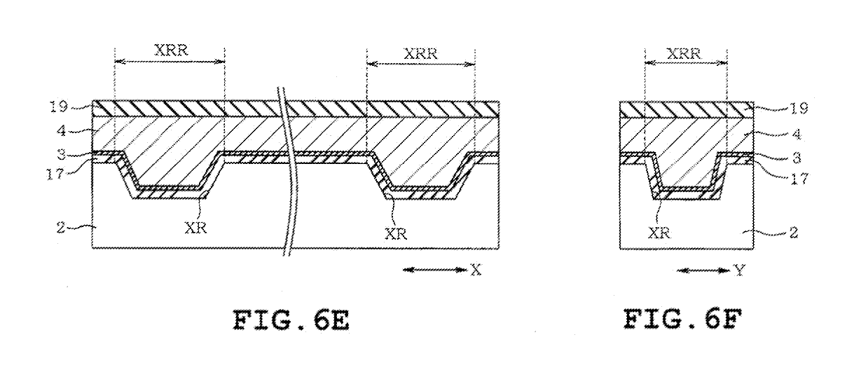

Next, as illustrated in FIGS. 6A to 6F, a polycrystalline silicon film 4 is formed on the gate insulation film 3 using a Chemical Vapor Deposition (CVD) method. Therefore, as illustrated in FIGS. 6E and 6F, the polycrystalline silicon film 4 extends inwardly of the recessed portions XR of the resistance element R on the gate insulation films 17 and 3. Here, it is preferable that the upper surface of the polycrystalline silicon film 4 of the resistance element R be planarized using a CMP method and the like. Thereafter, a dopant is doped into the polycrystalline silicon film 4 using an ion implantation method. As a result, the conductivity and conductivity type (n or p) of the polycrystalline silicon film 4 is adjusted so as to have a predetermined dopant concentration of p-type or n-type dopants. This doping of the polycrystalline film of the resistor can be performed using a mask and ion implantation, and other regions of the polycrystalline silicon layer may also be doped using a patterned mask and ion implant or diffusion techniques. Subsequently, a silicon nitride film 19 is formed on the polycrystalline silicon film 4. Alternatively, in the formation of the polycrystalline silicon film 4, the polycrystalline silicon film 4 of the p-type may be deposited by introducing boron as a dopant during deposition using the CVD method. For a portion in which the polycrystalline silicon film 4 of the n-type is formed, the polycrystalline silicon film 4 of the p-type is selectively removed. Thereafter, unnecessary polycrystalline silicon film 4 of the n-type is selectively removed after forming the polycrystalline silicon film 4 of the n-type using the same method. It is also possible to realize the configuration illustrated in FIGS. 6A to 6F using this method.

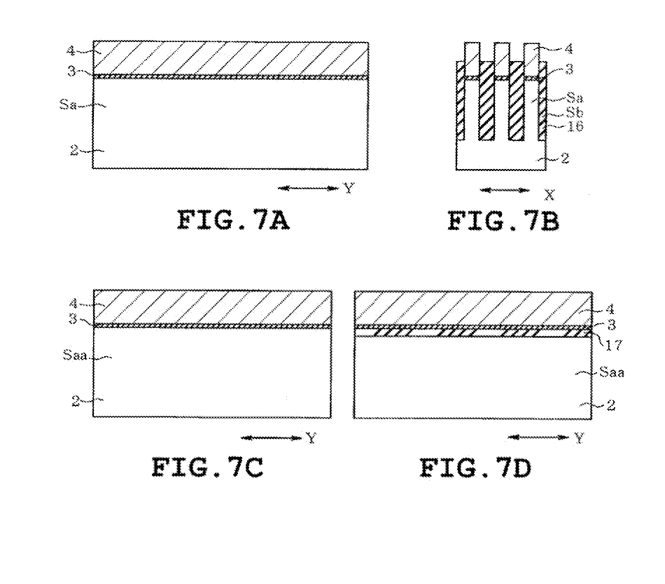

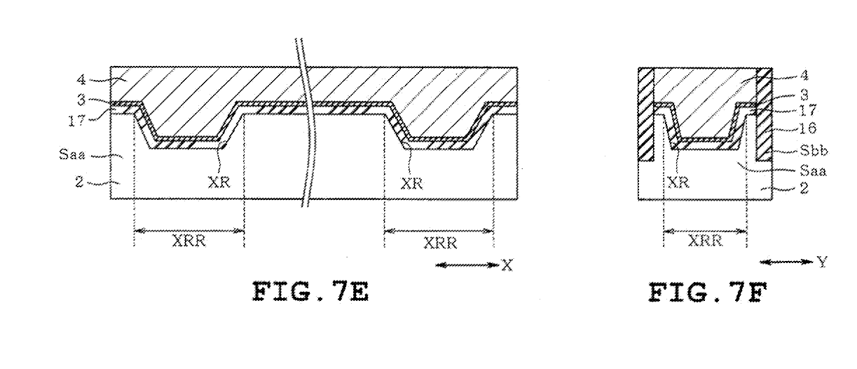

Next, as illustrated in FIGS. 7A to 7F, a resist mask for forming the element formation region Sa and the element isolation region Sb is formed using photolithography. Subsequently, anisotropic etching is performed by the RIE method using the resist mask. Therefore, the silicon nitride film 19, the polycrystalline silicon film 4, the gate insulation film 3, and the gate insulation film 17 are sequentially removed and the element isolation groove is formed in the silicon substrate 2. Here, it is preferable that the bottom surface of the element isolation groove be lower than that of the recessed portion XR.

Next, the silicon oxide film is formed so as to fill the inside of the element isolation grooves and the silicon oxide film formed on the silicon nitride film 19 is removed using a chemical mechanical polishing (CMP) method. In this case, the silicon nitride film 19 may be used as a polishing stop layer when polishing by CMP. Therefore, it is possible to embed the element isolation insulation film 16 inside the element isolation groove. Thereafter, the silicon nitride film 19 is removed using, for example, hot phosphoric acid. The element formation regions Sa and Saa, and the element isolation regions Sb and Sbb are defined by the process. Here, it is preferable that the bottom surface of the element isolation insulation film 16 be lower than the bottom surface of the polycrystalline silicon film 4 formed inside the recessed portion XR.

Thereafter, the element isolation insulation film 16 embedded in the element isolation grooves of the memory cell region is selectively etched. In the etching, as illustrated in FIG. 7B, the upper surface of the element isolation insulation film 16 is removed so as to position the surface thereof extending from the element isolation groove at substantially the middle portion of the polycrystalline silicon film 4 and as illustrated in FIG. 7F, the upper surface of the element isolation insulation film 16 extends the same height as that of the upper surface of the polycrystalline silicon film 4 in the peripheral circuit region, i.e., their upper surfaces are generally co-planar.

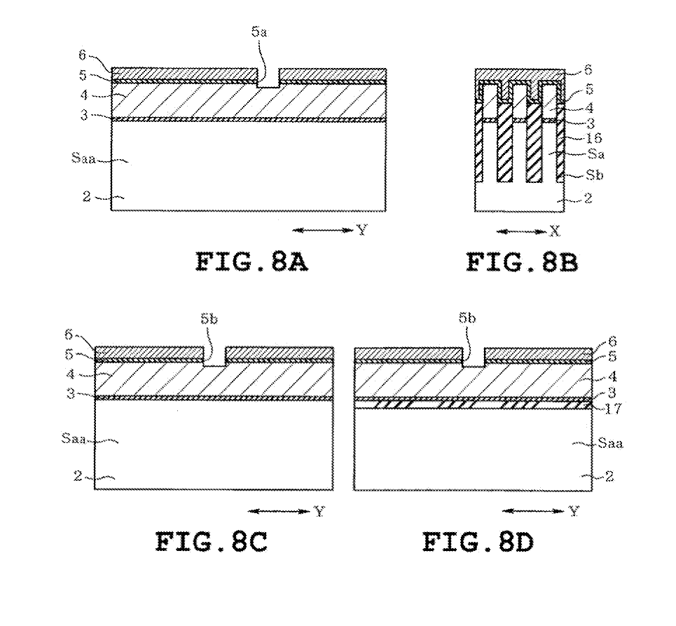

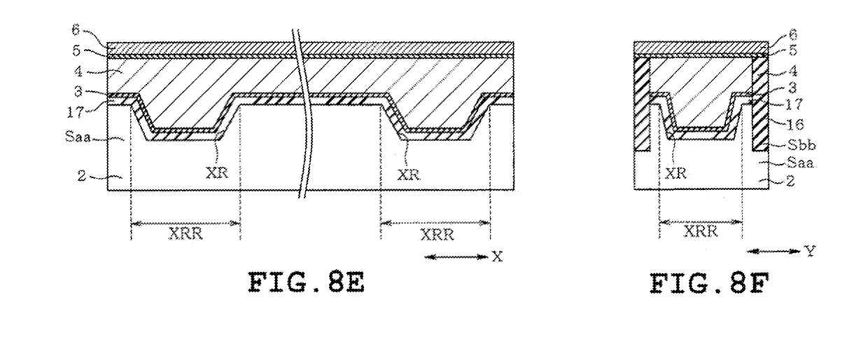

Next, as illustrated in FIGS. 8A to 8F, the inter-electrode insulation film 5 and the polycrystalline silicon film 6 are formed on the entire surface of the substrate. For example, the inter-electrode insulation film 5 may be formed as an ONO (oxide/nitride/oxide) film. The polycrystalline silicon film 6 may be formed using a CVD method. Thereafter, for example, boron is doped into the polycrystalline silicon film 6 using the ion implantation method and thereby forming polycrystalline silicon of the p-type.

Subsequently, a portion of the polycrystalline silicon film 6 and the inter-electrode insulation film 5 is selectively removed using a photolithography formed patterned mask in a portion thereof corresponding to the gate electrode SG of the select gate transistor Trs and in a portion thereof corresponding to the gate electrode PG of the transistors TrPLV and TrPHV of the peripheral circuit, and the opening portions 5a and 5b are formed.

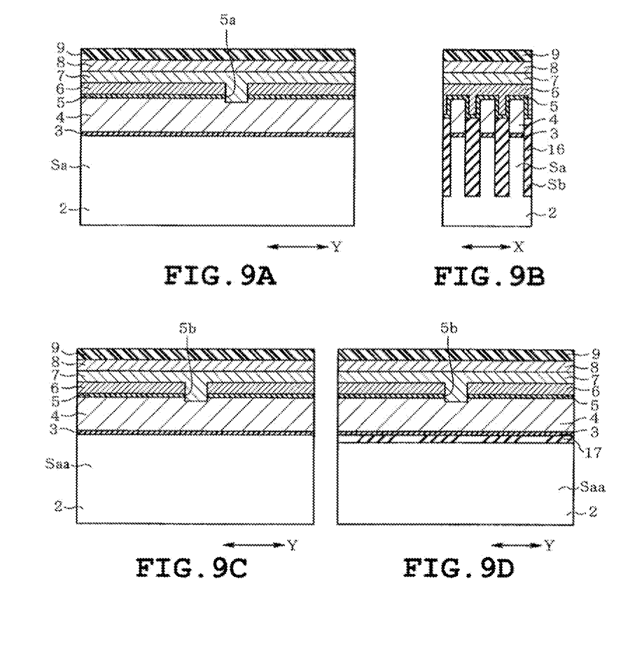

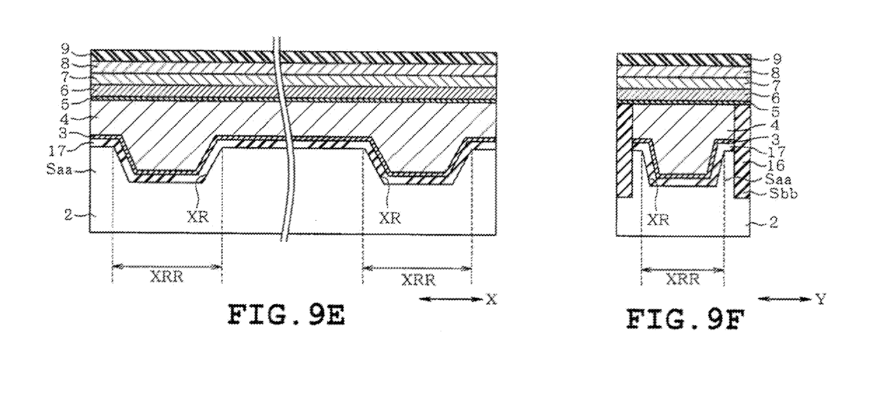

Next, as illustrated in FIGS. 9A to 9F, for example, a non-doped polycrystalline silicon film 7 is formed on the entire surface of the substrate (on polycrystalline silicon film 6) using the CVD method and, for example, boron is doped into the polycrystalline film 7 using ion implantation method, thereby forming the polycrystalline silicon of the p-type. In the opening portions 5a, 5b the polycrystalline silicon film 7 contacts the polycrystalline silicon film 4 through opening portions 5a, 5b. Therefore, electrical contact is made between the polycrystalline silicon film 4, the polycrystalline silicon film 6, and the polycrystalline silicon film 7.

Next, the metal film 8 and the silicon nitride film 9 are sequentially formed on the exposed surfaces of the substrate. For the metal film 8, tungsten (W) may be deposited, for example, by a sputtering method. The silicon nitride film 9 may be formed using the CVD method. Moreover, here, a tungsten nitride (WN) and the like may be formed as a barrier film between the polycrystalline silicon film 7 and the metal film 8.

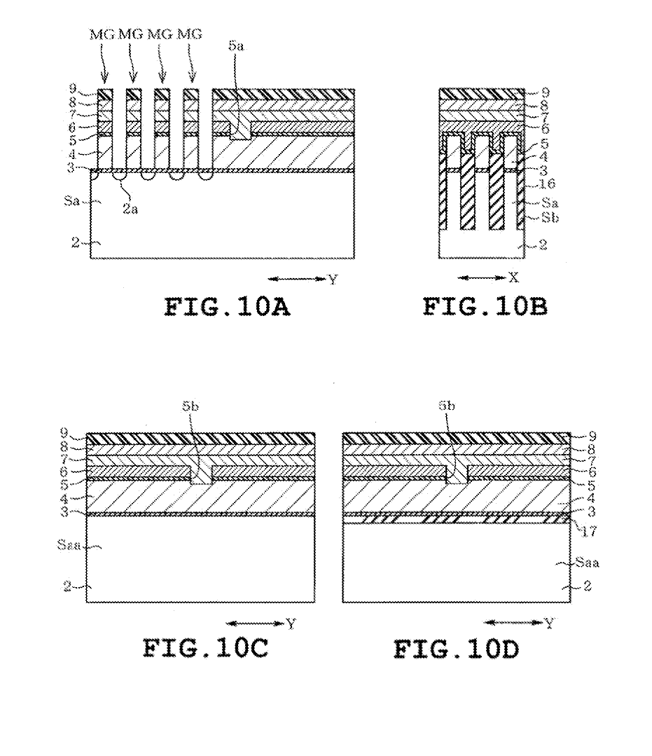

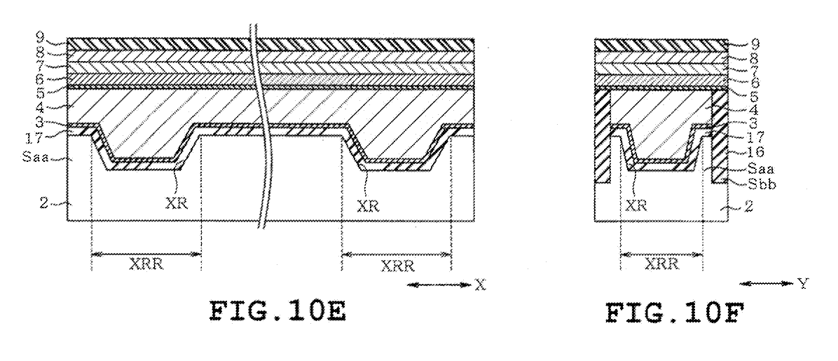

Next, as illustrated in FIGS. 10A to 10F, the gate electrodes MG of the memory cell transistor Trm are formed. The gate electrode MG forming process uses a patterned resist as an etch mask, and the individual gate electrodes MG are defined by anisotropic etching using the RIE method. In the process by the anisotropic etching, the silicon nitride film 9, the metal film 8, the polycrystalline silicon films 7, 6, the inter-electrode insulation film 5, and the polycrystalline silicon film 4 are sequentially removed by etching. A side surface of the select gate transistor Trs on the side of the memory cell transistor Trm of the gate electrode SG is also processed by the process. Subsequently, a dopant is doped into the silicon substrate 2 at the base of the opening extending between the gate electrodes MG and between the gate electrodes MG-SG by ion implantation. As the dopant, phosphorus may be used. The source/drain region 2a of the memory cell transistor Trm is formed by this process.

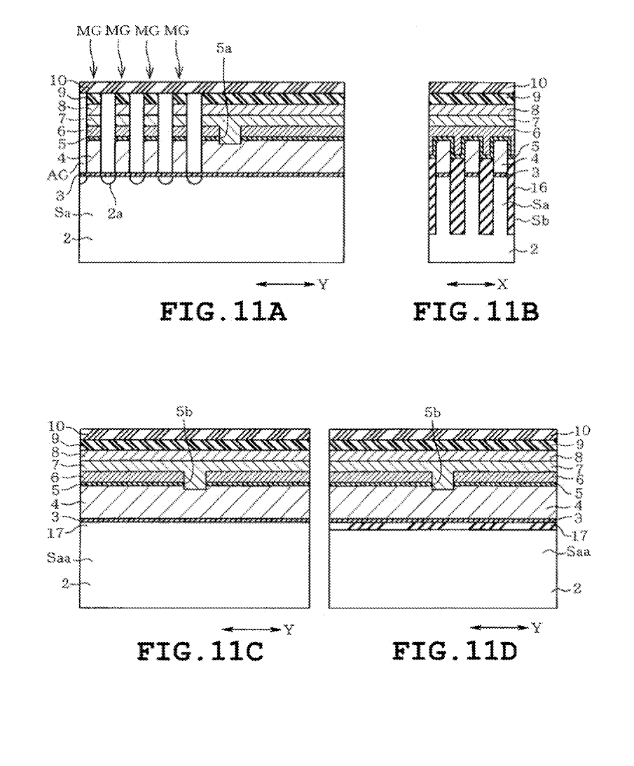

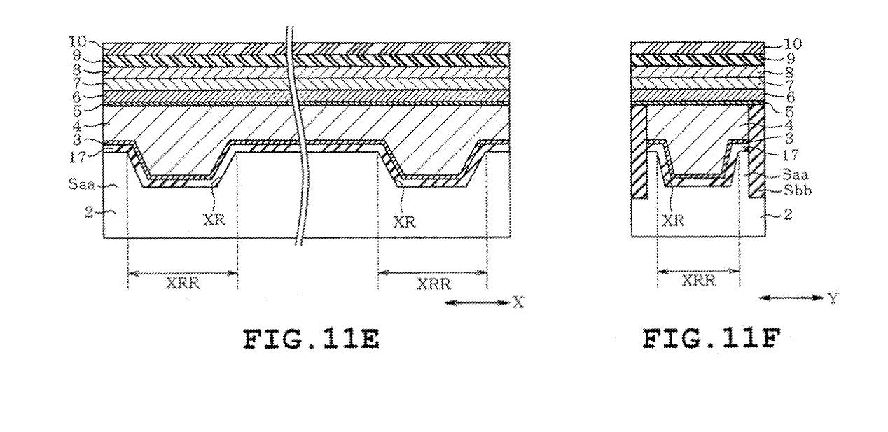

Next, as illustrated in FIGS. 11A to 11F, the insulation film 10 is formed on an entire surface. For example, a silicon oxide film is formed using the CVD method. In this case, the insulation film 10 is formed under conditions of low coatability, that is, under conditions where a narrow region is not filled. Gaps between the gate electrodes MG of the memory cell transistor Trm and between the gate electrode SG and the gate electrode MG of the select gate transistor Trs are narrow. Therefore, as illustrated in FIG. 11A, the insulation film 10 is formed on the upper section so as to cover gaps between the gate electrodes MG of the memory cell transistor Trm and between the gate electrode SG and the gate electrode MG of the select gate transistor Trs without filling in between the gate electrodes MG of the memory cell transistor Trm and between the gate electrode SG and the gate electrode MG of the select gate transistor Trs.

As a result, it is possible to form the air gap AG between the gate electrodes MG of the memory cell transistor Trm and between the gate electrode SG and the gate electrode MG of the select gate transistor Trs without filling them with the insulation film 10. It is possible to decrease an inter-wiring capacity between the gate electrodes MG by using the air gap AG structure.

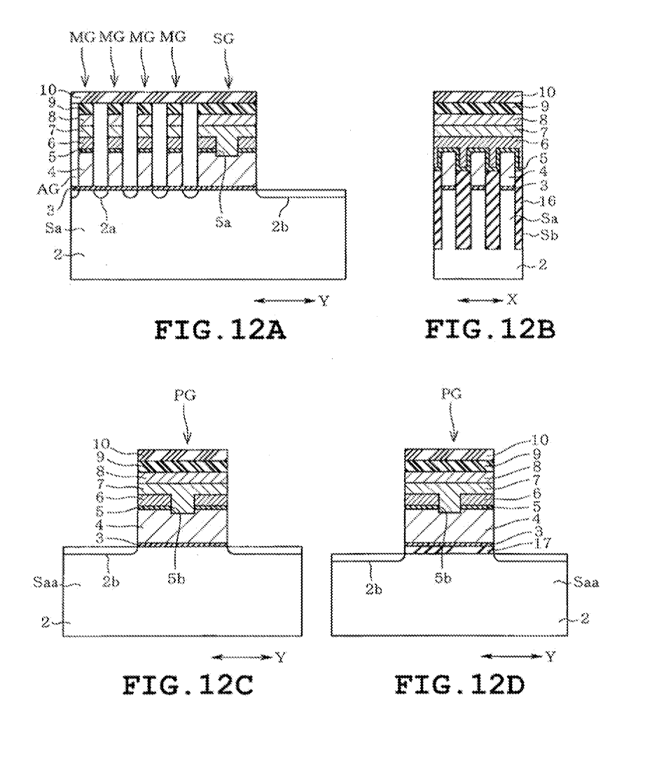

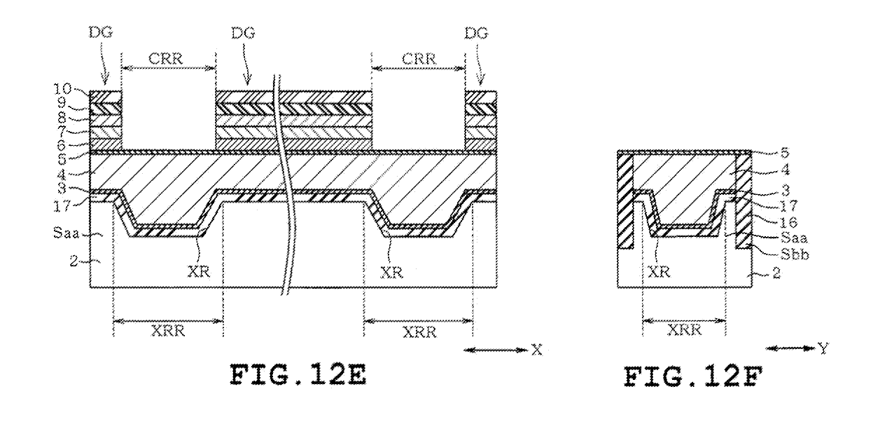

Next, as illustrated in FIGS. 12A to 12F, the gate electrode SG of the select gate transistor Trs, and the gate electrode PG of the transistors TrPLV and TrPHV of the peripheral circuit PC are formed. Here, a mask pattern for etching is formed using photolithography and anisotropic etching is performed through openings in the mask by the RIE method. In the anisotropic etching, the void forming insulation film 10, the silicon nitride film 9, the metal film 8, the polycrystalline silicon films 7 and 6, the inter-electrode insulation film 5, and the polycrystalline silicon film 4 are sequentially removed. At this time, it is also possible to remove the gate insulation film 3 and the gate insulation film 17.

Thereafter, for example, phosphorus having a low concentration is doped into the source/drain region on the side facing the gate electrode SG of the select gate transistor Trs and the source/drain region of a transistor Trn of an n-channel type of the transistors TrPLV and TrPHV of the peripheral circuit. Similarly, for example, boron having a low concentration is doped into the source/drain region of a transistor Trp of a p-channel type. Therefore, it is possible to form the low concentration source/drain region 2b in the LDD structure of the transistor.

Next, the dummy gate section DG of the resistance element R is formed. For example, openings are formed in the resist mask where the dummy gates DG are formed using photolithography, and anisotropic etching is performed using the RIE method. In the anisotropic etching, the void forming insulation film 10, the silicon nitride film 9, the metal film 8, the polycrystalline silicon films 7 and 6 are sequentially removed. Moreover, the inter-electrode insulation film 5 may be also removed using anisotropic etching. Thereafter, the resist mask is removed. As a result, it is possible to form the dummy gate section DG so as to sandwich the formation region CRR of the contact CR between adjacent dummy gates DG.

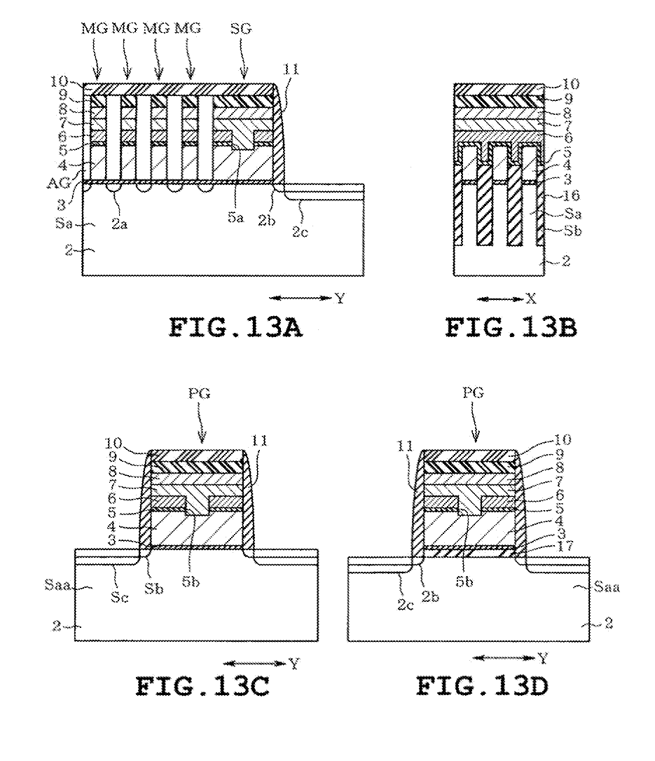

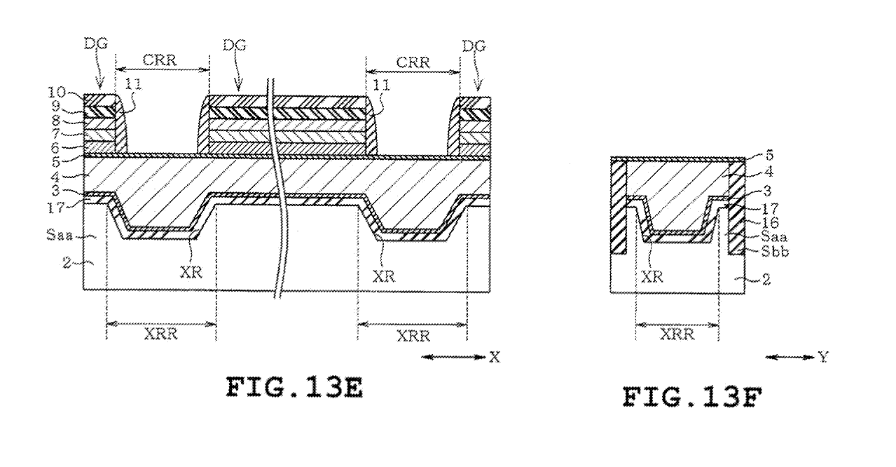

Next, as illustrated in FIGS. 13A to 13F, the insulation film such as the silicon oxide film having a predetermined film thickness is formed using the CVD method under conditions of favorable coatability. Thereafter, the insulation film is subject to etch-back process by etching the entire surface with the anisotropic etching using the RIE method and the spacer 11 ranging from the height of the upper surface to the height of the surface of the silicon substrate 2 is formed on the side surfaces of the gate electrodes SG and PG, and the dummy gate section DG of the resistance element R.

Next, a dopant is doped into the source/drain region on the side facing the select gate transistor Trs and the source/drain region of the transistor Trn of the n-channel type of the transistors TrPLV and TrPHV of the peripheral circuit. The dopant is, for example, boron, and a high concentration of boron is doped using an ion implantation method. The dopant is not doped into the portion of the substrate 2 where the spacer 11 is provided and, as a result, it is possible to form the high concentration source/drain region 2c in the LDD structure of the transistor.

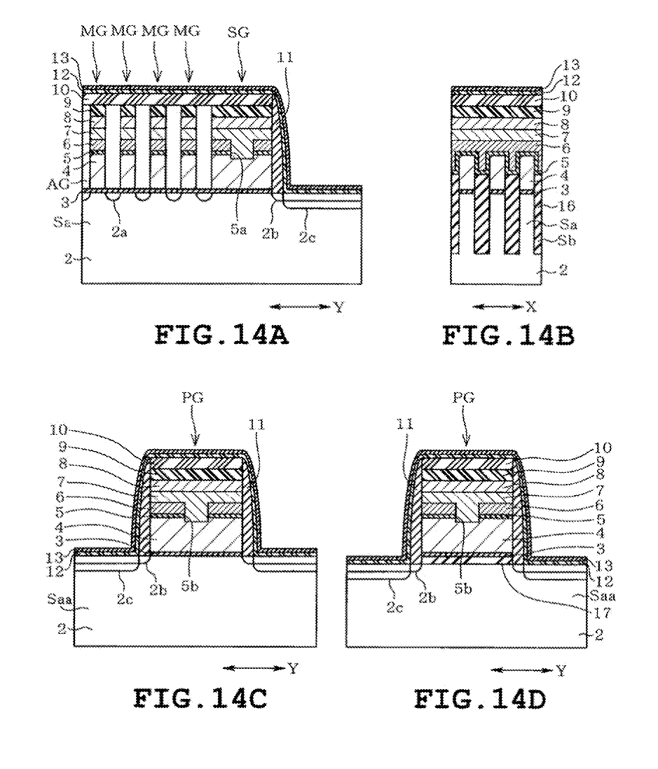

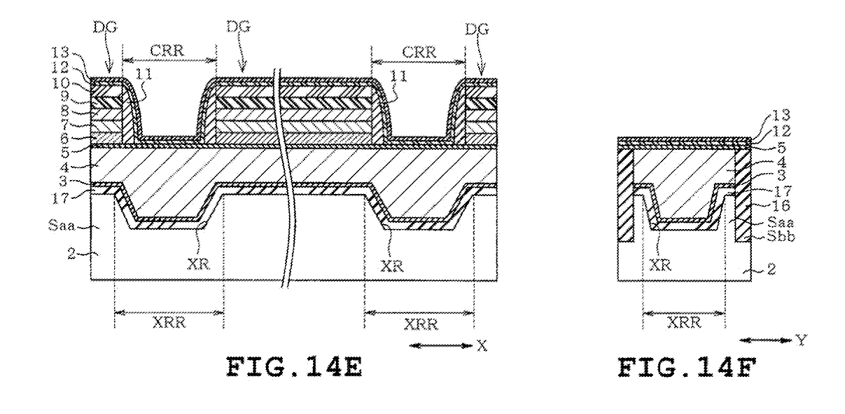

Next, as illustrated in FIGS. 14A to 14F, the silicon oxide film 12 and the silicon nitride film 13 are sequentially formed so as to cover the upper exposed surfaces on the silicon substrate 2. It is possible to form the silicon oxide film 12 and the silicon nitride film 13 using the CVD method. Therefore, the upper surface of the insulation film 10 of the memory cell region, the side surface of the spacer 11 facing the selector gate transistor Trs, and exposed surfaces of the silicon substrate 2 are covered by the silicon oxide film 12 and the silicon nitride film 13. Furthermore, the upper surface of the gate electrode PG of the transistors TrPLV and TrPHV of the peripheral circuit, the surface of the spacer 11 on the side wall, and the exposed portions of the upper surface of the silicon substrate 2 are covered by the silicon oxide film 12 and the silicon nitride film 13. Furthermore, the upper surface of the dummy gates DG of the resistance elements R, the surface of the spacer 11 of the side wall, and the upper surface of the inter-electrode insulation film 5 are covered by the silicon oxide film 12 and the silicon nitride film 13.

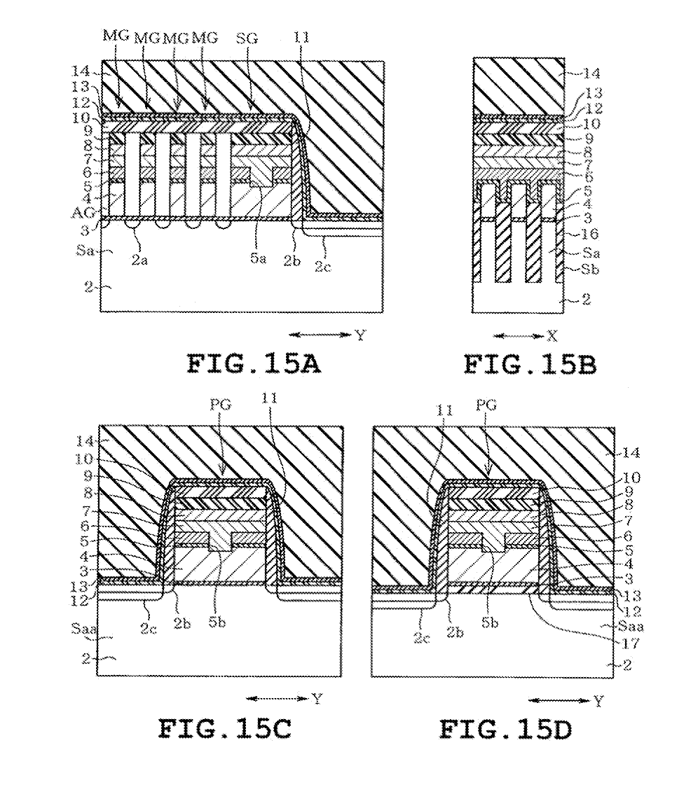

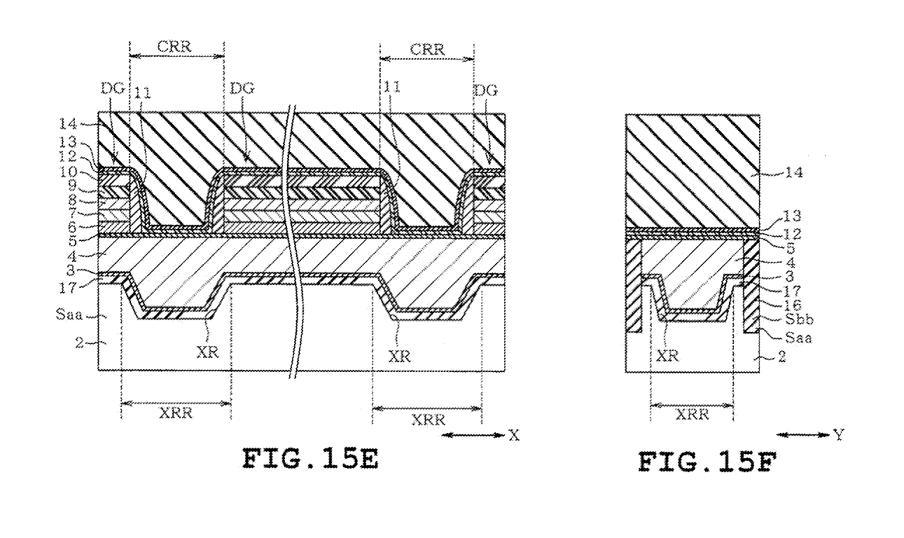

Next, as illustrated in FIGS. 15A to 15F, the interlayer insulation film 14 is formed on the upper surface of the silicon nitride film 13 that is formed by the processes described above. The interlayer insulation film 14 fills the recessed portion of the silicon substrate 2 between the gate electrodes SG and SG, and the upper surface thereof is formed to be flat. The interlayer insulation film 14 fills the formation region CRR of the contact CR of the resistance element R. The interlayer insulation film 14 may be planarized by performing polishing by the CMP method after forming the film.

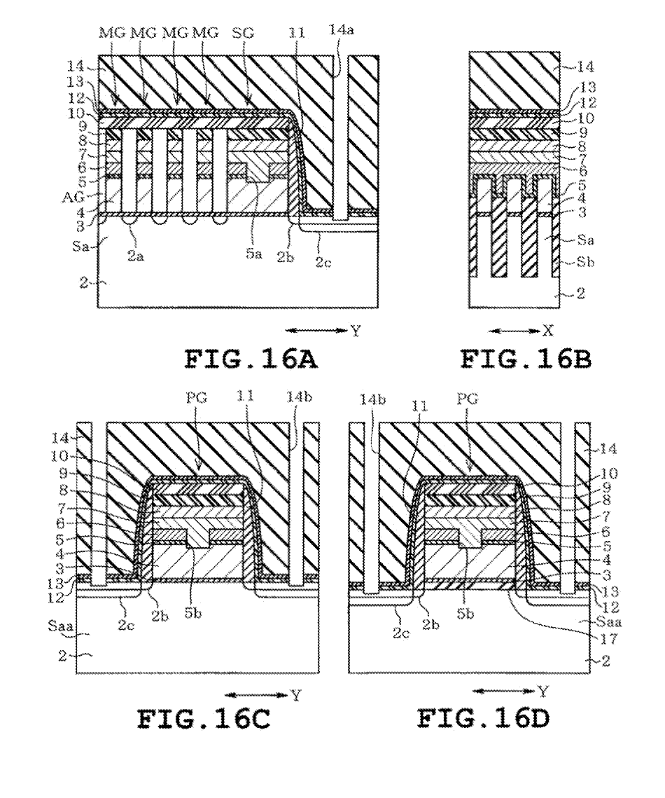

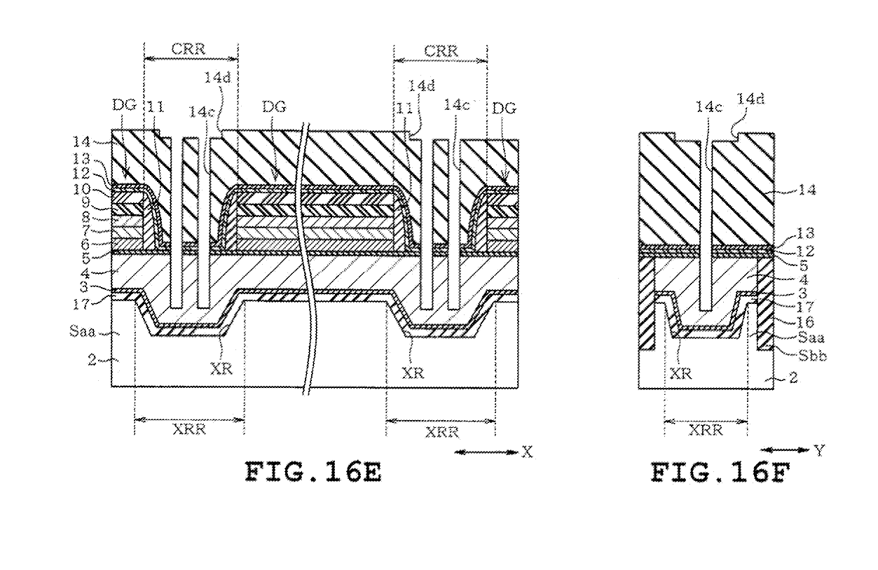

Next, as illustrated in FIGS. 16A to 16F, contact holes 14a to 14c and a wiring groove 14d are formed in the interlayer insulation film 14. Here, the contact hole 14a, each contact hole 14b of the transistors TrPLV and TrPHV of the peripheral circuit region, and the contact hole 14c of the resistance element R are simultaneously formed.

The contact holes 14a and 14b are formed so as to reach the surface of the silicon substrate 2 from the upper surface of the interlayer insulation film 14. The contact hole 14c of the resistance element R is formed so as to reach the polycrystalline silicon film 4 from the upper surface of the interlayer insulation film 14. The contact hole 14c of the resistance element R reaches the upper surface of the silicon nitride film 13 faster than the contact holes 14a and 14b. It is possible to etch the silicon nitride film 13 by setting a selection ratio (selectivity) of the etching species such that the silicon nitride film can function as an etching stop layer.

However, the silicon nitride film 13 at the resistance element R location is removed by etching until the contact holes 14a and 14b reach the lower surface of the silicon nitride film 13. In this case, the polycrystalline silicon film 4 is then etched as the contact hole 14c is extended thereinto. However, the bottom surface section of the polycrystalline silicon film 4 of the resistance element R extends deeper into the substrate than in the memory cell region or the upper surface of the silicon substrate 2 of the high withstand voltage transistor TrPHV, by the depth of the recessed portion XR. Thus, it is possible to control the etched depth of contact hole 14c such that it terminates within the polycrystalline silicon film 4 before reaching the surface of the silicon substrate 2. Therefore, it is possible to simultaneously form the contact holes 14a to 14c. Thereafter, the wiring groove 14d, a wiring groove, or the like (not illustrated) of the other portion corresponding to the resistance element R is formed on a surface layer portion of the interlayer insulation film 14 by etching through a photolithography formed patterned mask.

Thereafter, as illustrated in FIGS. 3A to 3F, the contact plugs 15a to 15c and wiring 18 are formed. For the contact plugs 15a to 15c and the wiring 18, a metal film is formed in the contact holes 14a-14c and the wiring groove 14d, and on the upper surface of the interlayer insulation film 14 after the processes described above, and the metal film is removed from the surface of the interlayer insulation film 14 leaving the metal film inside the contact holes 14a to 14c and inside the wiring groove 14d by etching, CMP, or the like. The contact plugs 15a to 15c and the wiring 18 are formed by a so-called dual damascene method. For the contact plugs 15a to 15c and the wiring 18, it is possible to use a tungsten (W) film in which titanium nitride (TiN) is used as a barrier film. The contact plugs 15a to 15c and the wiring 18 are formed by the processes described above.

The NAND type flash memory device according to the first embodiment is formed by the manufacturing method described above.

According to the NAND type flash memory device having the configuration described above, in the configuration of the resistance element R as a peripheral circuit element formed in the peripheral circuit region, the recessed portion XR is formed in the silicon substrate 2 in the bottom section of the portion in which the contact hole 14c is formed, and the polycrystalline silicon film 4 is provided therein. Therefore, in the etching of the contact hole 14c, it is possible to perform etching of a dual damascene structure simultaneously with the other contact holes 14a and 14b. Then, even if the contact hole 14c is deeply formed, it is possible to prevent contact between the contact hole 14c, and thus the contact 15c formed therein, and the silicon substrate 2. As a result, it is possible to form the contact 15c in a state of being reliably in contact with the polycrystalline silicon film 4.

In the case described above, one layer of the silicon nitride film 13 is provided in the formation region of the contact hole 14c of the resistance element R. Thus, etching of the contact hole 14c may be slowed or stopped until the other contact holes 14a and 14b reach the silicon nitride film 13 directly adjacent to the substrate 2 in the process of the formation of the contact hole 14c. Even in such a configuration, it is possible to form the contact hole 14c in a state in which the contact hole 14c reaches the layer of the polycrystalline silicon film 4. It is possible to avoid a problem that the contact CR comes into contact with the silicon substrate 2.

Furthermore, in some cases, the bottom section of the contact hole 14c may be positioned below the height of the upper surface of the silicon substrate 2 at locations other than the recessed region XRR, or may be positioned above thereof but in the polycrystalline silicon film 4 by employing the processes described above. In other words, even when there are variations in the etched depth of the contact holes 14a-14c, it is possible to form the contact plug 15c to terminate within the polycrystalline silicon film layer 4.

### Second Embodiment

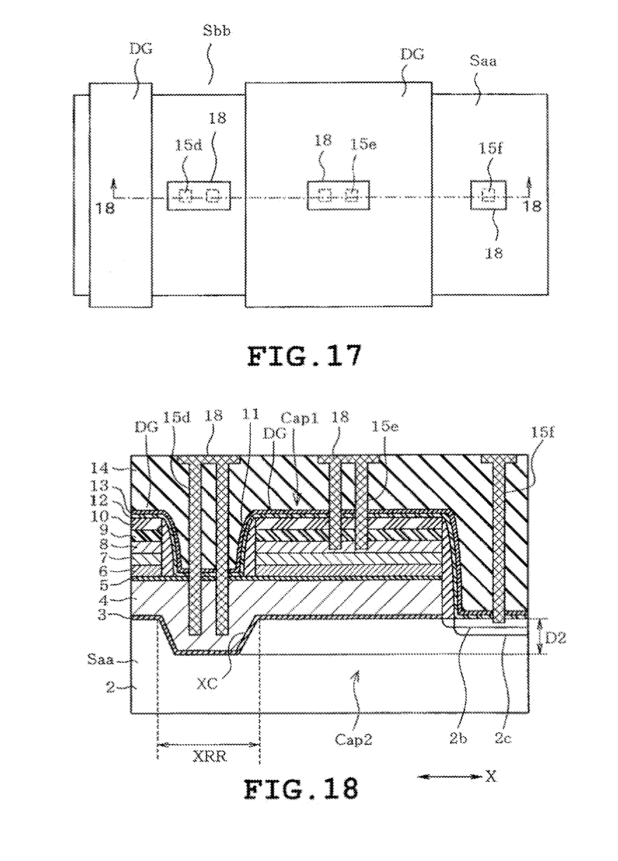

FIGS. 17 and 18 illustrate a second embodiment. Here, two capacitors Cap1 and Cap2 are provided as the peripheral circuit element. The first capacitor Cap1 is configured such that the polycrystalline silicon film 4 is one electrode and the polycrystalline silicon films 6 and 7 and the metal film 8 formed in the upper section thereof are the other electrode, and the intervening inter-electrode insulation film 5 is the dielectric film. The second capacitor Cap2 is configured such that the polycrystalline silicon film 4 is one electrode and the silicon substrate 2 is the other electrode, and the intervening insulation film 3 is the dielectric. A capacity of the first capacitor Cap1 is determined by a facing distance and a facing area of portions facing between the polycrystalline silicon film 4 and the polycrystalline silicon film 6 across the inter-electrode insulation film 5, and the dielectric constant of the inter-electrode insulation film 5. A capacity of the second capacitor Cap2 is determined by a facing distance and a facing area of portions facing between the polycrystalline silicon film 4 and the silicon substrate 2 across the gate insulation film 3, and the dielectric constant of the gate insulation film 3. A basic configuration of the film is the same as that of the resistance element R illustrated in the first embodiment. However, the gate insulation film 17 is not formed and only the gate insulation film 3 is formed.

Similar to the resistance element R, the rectangular element formation region Saa is provided in the silicon substrate 2 by the surrounding element isolation region Sbb filled with the element isolation insulation film 16. The size of the rectangular element formation region Saa is set in accordance with the capacity of the capacitor Cap. Furthermore, a plurality of capacitors Cap is formed by forming the element formation region Saa having a predetermined shape. It is possible to configure the capacitor provided in the peripheral circuit by connecting the plurality of capacitors Cap in series or in parallel.

In FIG. 18, the height of the surface of the silicon substrate 2 is processed so as to be the same height as the memory cell region or the upper surface of the silicon substrate 2 of the low withstand voltage transistor TrPLV. The gate insulation film 3 for the low withstand voltage is formed as the third insulation film on the upper surface of the silicon substrate 2.

Furthermore, in the element formation region Saa of the capacitors Cap1 and Cap2, a recessed portion XC is formed in a portion of the recessed region XRR of the surface of the silicon substrate 2. A bottom surface of the recessed portion XC is lower than the surface of the silicon substrate 2 other than the concave portion region XRR by the depth D2 at least in a region that is positioned below the contact plug 15d. The recessed portion region XRR is set in a region corresponding to a portion in which at least the contact plug 15d is disposed, but is not limited to the embodiment and may be provided to be suitably extended, and may be set in a narrower region. Furthermore, the recessed region XRR may be an entire region in which the capacitor Cap is formed.

The gate insulation film 3 is formed on the upper surface of the silicon substrate 2. For the gate insulation film 3, a silicon oxide film may be used. Furthermore, the gate insulation film 3 may be formally formed now on the surface of the recessed portion XC. The polycrystalline silicon film 4 that is one electrode of the capacitor Cap is formed on the upper surface of the gate insulation film 3 so as to fill the recessed portion XR. For example, phosphorus or arsenic as the dopant is doped in the polycrystalline silicon film 4 and then the polycrystalline silicon film 4 is n-type polycrystalline silicon. Furthermore, the upper surface of the polycrystalline silicon film 4 may be flat. Furthermore, the upper surface of the polycrystalline silicon film 4 may be flush with the upper surface of the element isolation insulation film 16. The inter-electrode insulation film 5 that is the fourth insulation film is provided on the upper section of the polycrystalline silicon film 4.

The polycrystalline silicon films 6 and 7, and the metal film 8 are provided in a region of the upper section of the inter-electrode insulation film 5 other than a region corresponding to the upper section of the recessed portion XC (corresponding to the film configuration that configures the control gate electrode in the memory cell transistor Trm). The silicon nitride film 9 and the void forming insulation film 10 are provided on the upper section of the metal film 8. The portions of the inter-electrode insulation film 5, the polycrystalline silicon films 6 and 7, and the silicon nitride film 8 form the dummy gates DG.

The spacer 11 is formed on the side wall of the dummy gates DG using a silicon oxide film. The silicon oxide film 12 and the silicon nitride film 13 are formed so as to cover the upper surface of the dummy gates DG and the surface of the second insulation film 5 that is exposed between the side surface of the spacer 11 and the dummy gates DG.

For example, the interlayer insulation film 14 is a silicon oxide film and fills the concave portion between the dummy gates DG, and is formed on the upper surface of the silicon nitride film 13 so as to cover the dummy gates DG. Two contact plugs 15d, which reach the inside of the polycrystalline silicon film 4 by passing through the interlayer insulation film 14, the silicon nitride film 13, the silicon oxide film 12, and the inter-electrode insulation film 5 from the upper surface thereof, are formed in the portion of the concave portion XC in which the dummy gates DG are not formed. The contact plug 15d functions as one electrode.

A lower end of the contact plug 15d is positioned inside the polycrystalline silicon film 4. In FIG. 18, the lower end of the contact plug 15d is in a position higher than the surface of the silicon substrate 2 below the recessed region XRR. Moreover, the lower end of the contact plug 15d may be at a position higher than the surface of the silicon substrate 2 other than the recessed region XRR as long as the lower end thereof is positioned inside the polycrystalline silicon film 4. In this case, in the lower section of the contact plug 15d, since the polycrystalline silicon film 4 is deeply formed in the silicon substrate 2, the lower end of the contact plug 15d is unlikely to reach the surface of the silicon substrate 2.

Two contact plugs 15e, which reach the inside of the metal film 8 or the polycrystalline silicon film 7 by passing through the interlayer insulation film 14, the silicon nitride film 13, the silicon oxide film 12, the insulation film 10, and the silicon nitride film 9 from the upper surface thereof, are formed on the upper surface of the dummy gate DG on the side on which the capacitor Cap is configured. The contact plugs 15e function as the other electrode. It is possible to form the contact plugs 15e in the process in which other contact plugs such as the gate electrode SG or PG are formed.

A lower end of a contact plug 15f is positioned in the LDD region 2b formed in the silicon substrate 2.

In the configuration described above, the recessed portion XC is provided in the silicon substrate 2 of the formation region of the contact plug 15d and the film thickness of the polycrystalline silicon film 4 in the portion is thick in the configuration in which the capacitors Cap1 and Cap2 is provided as the peripheral circuit element of the NAND type flash memory device 1. Therefore, since substantial film thickness of the polycrystalline silicon film 4 with which the contact plug 15d comes into contact is thick, the process window for forming the contacts may be increased in processing.

Furthermore, it is possible to increase a contact area between the gate insulation film 3 and the silicon substrate 2 by providing the recessed portion XR. As a result, it is possible to increase the capacity of the second capacitor Cap2.

Moreover, in the embodiment described above, although two contact plugs 15d are provided in one recessed portion XC with respect to the capacitors Cap1 and Cap2, a plurality of recessed portions XC may be provided.

### Other Embodiments

It is possible to modify the embodiment as the following in addition to the embodiment described above.

It is possible to form the recessed portions XR and XC by machining the silicon substrate 2 so as to have an appropriate tapered shape.

It is provided a configuration in which the gate insulation films 3 and 17 on the upper surface of the silicon substrate 2 of the capacitors Cap1 and Cap2 and the resistance element R that is the peripheral circuit element, but it may be provided a configuration in which either of the gate insulation films are used.

The resistance element R and the capacitors Cap1 and Cap2 may be formed by appropriately modifying planar layouts, shapes, sizes, or the like thereof so as to obtain a desired resistance value or capacitance value.

In the second embodiment, although a case having a configuration in which two capacitors Cap1 and Cap2 are provided is described, but it is also possible to apply a case where a configuration corresponding to one of the capacitors Cap1 and Cap2 is independently formed.

It is possible to apply the embodiment to a device other than the NAND type flash memory device.

Several embodiments are described, but these embodiments are presented as examples and are not intended to limit the scope of an exemplary embodiment. The novel embodiments are capable of being implemented in various other forms and it is possible to perform various omission, substitutions, and changes without departing from the scope of an exemplary embodiment. The embodiments or modifications thereof fall within the scope or the gist of the inserting and are within an exemplary embodiment described in the claims and the scope of equivalent thereof.

What is claimed is:

1. A semiconductor device comprising:
a memory cell transistor in which a first insulation film, a first conductive layer, a second insulation film, and a second conductive layer are sequentially stacked on a semiconductor substrate; and
a peripheral circuit element in which a third insulation film, a third conductive layer, a fourth insulation film, a fourth conductive layer are sequentially stacked on the semiconductor substrate and which has a contact electrically connected to the third conductive layer,
wherein in the semiconductor substrate, a recess is formed at least in a region immediately below the contact,
wherein the third conductive layer is also formed within the recess, and
wherein a film thickness of the third conductive layer in the recess is thicker than a film thickness of the first conductive layer.

2. The semiconductor device according to claim 1,
wherein a position of a lower end of the contact of the peripheral circuit element is located at a position lower than an upper surface of the portion of the semiconductor substrate in which the memory cell transistor is formed above the semiconductor substrate.

3. The semiconductor device according to claim 1,
wherein the peripheral circuit element is a resistance element and the third conductive layer functions as a resistor.

4. The semiconductor device according to claim 3,
wherein in the third conductive layer, a film thickness of the portion thereof functioning as the resistor is thinner than a film thickness of the third conductive layer in the recess.

5. The semiconductor device according to claim 1, further comprising:
a transistor in which a fifth conductive layer having the same material as that of the third conductive layer, a sixth insulation film, and a seventh conductive layer are laminated on the semiconductor substrate over the fifth insulation film,
wherein a film thickness of the fifth insulation film is thicker than a film thickness of the first insulation film.

6. The semiconductor device according to claim 1,
wherein the number of the contacts is two.

7. The semiconductor device according to claim 6,
wherein the two contacts are disposed in parallel along a longitudinal direction of the third conductive layer.

8. The semiconductor device according to claim 1,
wherein a side wall of the recess is tapered.

9. The semiconductor device according to claim 1, further comprising:
dummy gates between the contacts,
wherein a silicon nitride film is disposed between the dummy gates above the fourth insulation film.

10. The semiconductor device according to claim 9,
wherein the silicon nitride film is located at a position lower than an upper surface of the fourth conductive layer.

11. The semiconductor device according to claim 1,
wherein the peripheral circuit element is a capacitance element in which the fourth insulation film is a dielectric, the third conductive layer is one electrode, and the fourth conductive layer is the other electrode.

12. The semiconductor device according to claim 11,
wherein the peripheral circuit element is a capacitance element in which the third insulation film is the dielectric substance, the third conductive layer is one electrode, and the semiconductor substrate is the other electrode.

13. The semiconductor device according to claim 12,
wherein in the recess, a seventh insulation film is formed between the third conductive layer and the semiconductor substrate.

14. The semiconductor device according to claim 12,
wherein the thickness of the seventh insulation film is equal to the thickness of the first insulation film.

15. The semiconductor device according to claim 1,
wherein an upper surface of the semiconductor substrate at which a memory cell transistor is disposed is higher than a lower surface of the recess.

16. The semiconductor device according to claim 1,
wherein an upper surface of the semiconductor substrate at which a transistor is disposed is lower than the upper surface of the semiconductor substrate at which the memory cell transistor is disposed, and
wherein the upper surface of the semiconductor substrate at which the transistor is formed is higher than a lower surface of the recess.

17. A semiconductor device comprising:
a semiconductor substrate having a first surface;
a recess extending inwardly of the semiconductor substrate, and a polycrystalline silicon layer extending inwardly of the recess and overlying the semiconductor substrate adjacent to the recess;
at least one doped region of the substrate at a location spaced from the recess;
an insulating layer overlying the polycrystalline silicon layer and the doped region of the substrate, the depth of the insulating layer being greater over the doped region of the substrate as compared to the thickness thereof over the polycrystalline layer, and the thickness of the polycrystalline silicon layer in and overlying the recess and the thickness of the insulating layer overlying the polycrystalline silicon layer is greater than the thickness of the insulating layer overlying the doped region; and
at least one first contact extending through the insulating layer and extending into contact with the semiconductor substrate in the doped region and at least one second contact extending through the insulating layer and terminating within the polycrystalline silicon layer.

18. The semiconductor device according to claim 17, wherein the second contact extends inwardly of the recess.

19. A method of manufacturing a semiconductor device, comprising:
forming a first recess inwardly of the surface of a semiconductor layer;
forming polycrystalline silicon in the recess and over the substrate in a region adjacent to the recess;
forming an insulating material over the polycrystalline silicon layer and over the substrate in a region where the polycrystalline silicon layer is not present over the substrate; and
simultaneously etching at least a first opening through the insulating layer and into, and terminating within, the polycrystalline silicon layer and etching a second opening through the insulating layer in a region where the polycrystalline silicon layer is not present over the substrate to the surface of the substrate.

20. The method of claim 19, further comprising:
etching a second recess inwardly of the semiconductor substrate spaced from the first recess;
forming the polycrystalline silicon layer in the second recess and over the surface of the substrate between the first and second recesses; and
forming a dummy gate over the polycrystalline layer in the region thereof extending between the first recess and the second recess.
